(19) United States
(12) Patent Application Publication
(10) Pub. No.: US 2013/0328151 A1
(43) Pub. Date: Dec. 12, 2013

(54) INTEGRATED CIRCUIT STRUCTURE, BACK SIDE ILLUMINATION IMAGE SENSOR AND INTEGRATED CIRCUIT PROCESS THEREOF

(71) Applicant: Ching-Hung Kao, Hsinchu County (TW)

(72) Inventor: Ching-Hung Kao, Hsinchu County (TW)

(21) Appl. No.: 13/490,465

(22) Filed: Jun. 7, 2012

(51) Int. Cl. H01L 31/02; H01L 21/28

(52) U.S. Cl. 257/443; 438/612; 257/E31.113; 257/E21.158

(57) ABSTRACT

An integrated circuit structure or a back side illumination image sensor is provided, wherein the integrated circuit structure includes a bond pad and a metal structure located in a dielectric layer, wherein the bond pad and the metal structure have different materials, and the back side illumination image sensor includes an image sensor unit and an interconnect structure respectively located on both sides of a bond pad. Moreover, an integrated circuit process forming said integrated circuit structure or back side illumination image sensor is also provided.

### BACKGROUND OF THE INVENTION

1. Field of the Invention

The present invention relates generally to an integrated circuit structure, a back side illumination (BSI) image sensor and an integrated circuit process, and more specifically to an integrated circuit structure, a back side illumination (BSI) image sensor and an integrated circuit process that directly forms a bond pad on a substrate, and then forms an interconnect structure on the bond pad.

2. Description of the Prior Art

Back side illumination (BSI) image sensors are popular image sensors at present. Back side illumination (BSI) image sensors fabrication can be integrated into conventional semiconductor processes, and therefore back side illumination (BSI) image sensors have the advantages of low cost, small size, and high integration rate. Back side illumination (BSI) image sensor also have the advantages of low operating voltage, low power consumption, high quantum efficiency, low read-out noise, and random access. Therefore, back side illumination (BSI) image sensors are adopted broadly in electronic products, such as PC cameras and digital cameras.

A conventional back side illumination (BSI) image sensor structure may be divided by function into a light sensing area and a peripheral electronic circuit area. The light sensing area has a plurality of photodiodes arranged in an array, and MOS transistors to sense light intensity, i.e. a reset transistor, a current source follower and a row selector. The peripheral electronic circuit area connects interconnects to external connections. A main function of the back side illumination (BSI) image sensor is to divide incident beams into combinations of light of different wavelengths. The light is received by a plurality of imaging devices on the semiconductor substrate and transformed into digital signals of different intensities. For instance, an incident beam is divided into a combination of red, green and blue light and received by corresponding photodiodes. Each photodiode transforms the light intensity into digital signals.

### SUMMARY OF THE INVENTION

The present invention provides an integrated circuit structure, a back side illumination (BSI) image sensor and an integrated circuit process, which directly forms a bond pad on a front side of a substrate, forms an interconnect structure on the bond pad, and then etches the substrate to expose the bond pad, thereby enabling the bond pad to electrically connect outer circuits. Thus, the capabilities of conventional back side illumination (BSI) image sensors are enhanced.

The present invention provides an integrated circuit structure including a bond pad and a metal structure located in a dielectric layer, wherein the bond pad and the metal structure comprise different materials.

The present invention provides a back side illumination (BSI) image sensor including an image sensor unit and an interconnect structure respectively located on both sides of a bond pad.

The present invention provides an integrated circuit process including the following steps. A dielectric layer is formed on a front side of a substrate. A bond pad is formed on the substrate and in the dielectric layer. A first dielectric layer is formed on the bond pad and the dielectric layer. An interconnect structure is formed in the first dielectric layer. A recess is formed in a back side of the substrate to expose the bond pad.

According to the above, the present invention provides an integrated circuit structure, a back side illumination (BSI) image sensor and an integrated circuit process, which directly forms a bond pad on a substrate, forms an interconnect structure on the bond pad, and then etches the substrate to expose the bond pad, enabling the bond pad to electrically connect outer circuits. This way, the integrated circuit structure, the back side illumination (BSI) image sensor and the integrated circuit process have the following advantages: the problem of etching difficulty for exposing the bond pad is solved; the volume of the bond pad shrinks, so that the volume of the integrated circuit structure or the back side illumination (BSI) image sensor shrinks; a surface of an isolating layer used for connecting a carrier wafer can be flatter; antenna effect caused by the etching of a stacked inter metal dielectric (IMD) layer for filling the bond pad material will not occur.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically depicts a cross-sectional view of a back side illumination (BSI) image sensor according to an embodiment.

FIGS. 2-10 schematically depict cross-sectional views of an integrated circuit process according to an embodiment of the present invention.

### DETAILED DESCRIPTION

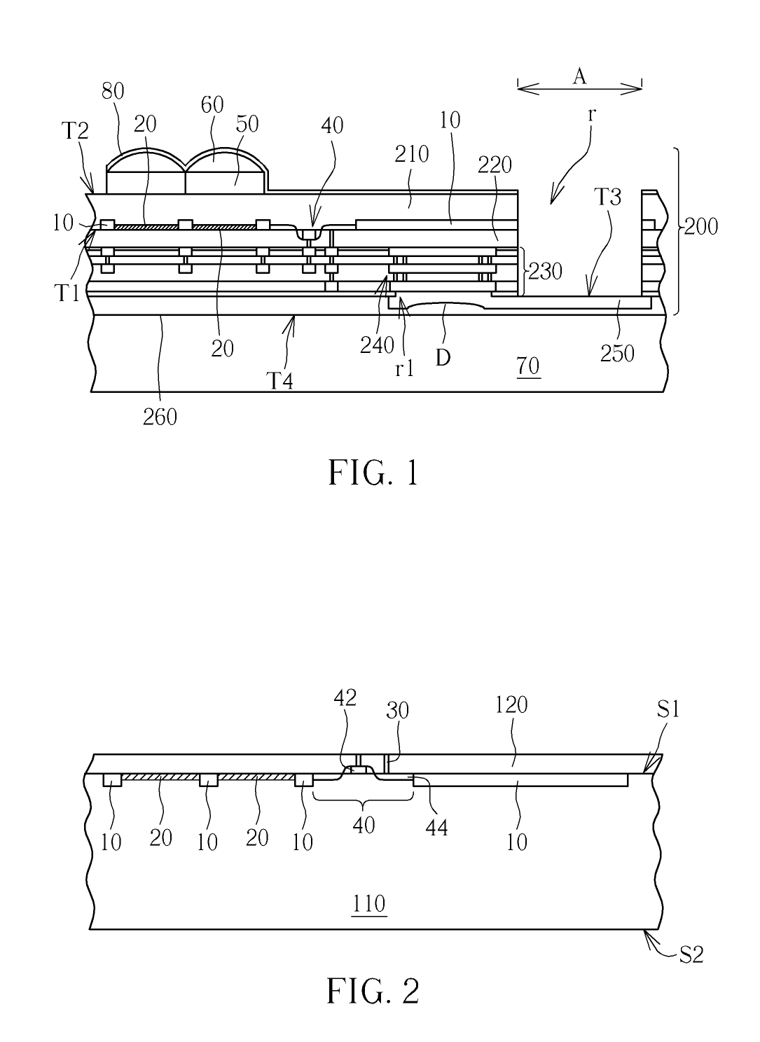

FIG. 1 schematically depicts a cross-sectional view of a back side illumination (BSI) image sensor according to an embodiment. As shown in FIG. 1, a substrate 210 has a front side T1 and a back side T2. A plurality of isolation structures 10 are located in the front side T1 of the substrate 210, and a photodiode array 20 and at least a MOS transistor 40 are located between each of the isolation structures 10. A plurality of color filter units 50 and microlenses 60 are located on the back side T2 of the substrate 210, and each of them is aligned with the photodiode array 20, enabling incident beams to be received and focused by the photodiode array 20. By doing this, the photodiode array 20 can sense the incident beams and then provide current to corresponding MOS transistors and transfer digital signals. A plurality of passivation layers 80 is located on the microlens 60. The passivation layers 80 may be nitride layers to prevent the microlens 60 from being in contact with the air, wherein components of the air, such as vapor, affects the microlens 60, can be avoided.

In the process, an interdielectric layer 220 is formed on the front side T1 of the substrate 210, a stacked inter metal dielectric (IMD) layer 230 layer is located on the interdielectric layer 220, and a multilayer interconnect structure 240 is located on the stacked inter metal dielectric (IMD) layer 230. A bond pad 250 connects the multilayer interconnect structure 240, so that the multilayer interconnect structure 240 can electrically connect outer circuits through a front side T3 of the bond pad 250 connecting to a bonding ball of a solder bump (not shown) or a bonding ball of a wire bond (not shown) or etc. An oxide layer 260 entirely covers the stacked inter metal dielectric (IMD) layer 230, the multilayer interconnect structure 240 and the bond pad 250. A carrier wafer 70 contacts the oxide layer 260 to load the back side illumination (BSI) image sensor 200. The substrate 210 is thinned down from the back side T2 and the color filter units 50 and the microlens 60 are sequentially formed.

It is emphasized that: (1) a part of the substrate 210, the interdielectric layer 220 and the stacked inter metal dielectric (IMD) layer 230 need to be etched to form a recess r and expose a part of the bond pad 250 in this embodiment, thereby enabling the back side illumination (BSI) image sensor 200 to electrically connect the outer circuits through the front side T3 of the bond pad 250. However, the recess r must be formed through etching the substrate 210, the interdielectric layer 220 and the stacked inter metal dielectric (IMD) layer 230, but it is too deep to etch, and difficulties of etching may arise. (2) The thickness and the size of the bond pad 250 must be large enough to provide enough strength to bear the impact force while bonding. However, an area A of the bond pad 250 protruding from the multilayer interconnect structure 240 and used for electrical contacts will occupy the layout space, and the volume of the back side illumination (BSI) image sensor 200 therefore increases. (3) The connection point of the bond pad 250 and the multilayer interconnect structure 240 has a divot D formed from a part of the bond pad material being filled into a recess r1 in the stacked inter metal dielectric (IMD) layer 230. But the oxide layer 260 formed on the bond pad 250 has to be smooth, so that the back side illumination (BSI) image sensor 200 can be connected to the carrier wafer 70 statically and closely, and the divot D will degrade the flatness of the surface T4 of the oxide layer 260. (4) The antenna effect occurs when the etching depth is too deep, which leads to charges drilling into the stacked inter metal dielectric (IMD) layer 230, thereby resulting in bad performances of the back side illumination (BSI) image sensor 200. (5) The color filter material in the recess r will splash as the color filter material is spin coated in latter processes, which decreases the uniformity of the thickness of the color filter units 50, and decreases the performances of the back side illumination (BSI) image sensor 200.

Therefore, an embodiment is presented in the hereafter to solve the problems of this embodiment.

FIGS. 2-10 schematically depict cross-sectional views of an integrated circuit process according to an embodiment of the present invention. A substrate 110 having a front side S1 and a back side S2 are provided. The substrate 110 may be a semiconductor substrate such as a silicon substrate, a silicon containing substrate, a III-V group-on-silicon (such as GaN-on-silicon) substrate, a graphene-on-silicon substrate or a silicon-on-insulator (SOI) substrate. A plurality of isolation structures 10 are formed on the front side S1 of the substrate 110. The isolation structures 10 may be shallow trench isolation structures, and formed by a shallow trench isolation process, but it is not limited thereto. A photodiode array 20 is formed between each of the isolation structures 10 to sense and receive incident beams, and at least a MOS transistor 40 is formed, which may be a reset transistor, a current source follower or a row selector used to transform the sensing beams into digital signals, a logical MOS transistor or a MOS transistor protection circuit against electrostatic discharges (ESD) in the periphery circuit region. Thereafter, a dielectric layer 120 is entirely formed on the front side S1 of the substrate 110. The dielectric layer 120 may be an interdielectric layer, which may be an oxide layer, but it is not limited thereto. Contact holes (not shown) are formed in the dielectric layer 120 through etching, and then at least a contact plug 30 is formed by filling conductive materials such as copper or tungsten in the contact holes (not shown) to respectively connect a gate 42 and a source/drain 44 of the MOS transistor 40. To specify and clarify the present invention, there are just two photodiodes included in the photodiode array 20 and one MOS transistor 40 in this embodiment, but the number of the photodiodes included in the photodiode array 20 and the MOS transistor 40 are not limited thereto. Besides, other semiconductor components such as other interconnect structures or others may also be disposed on the substrate 110 and in the dielectric layer 120.

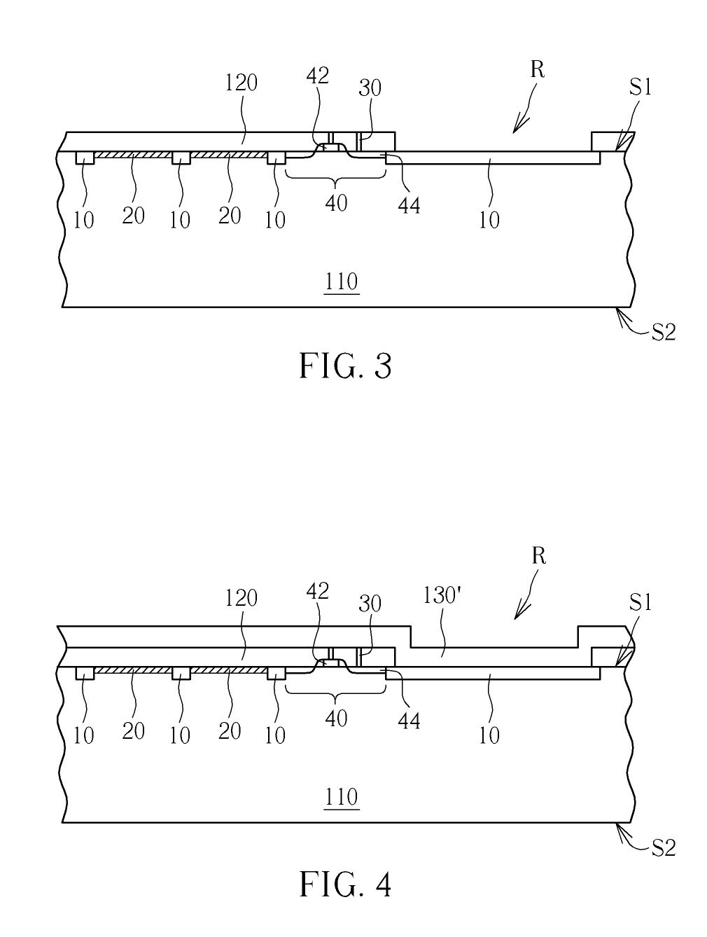

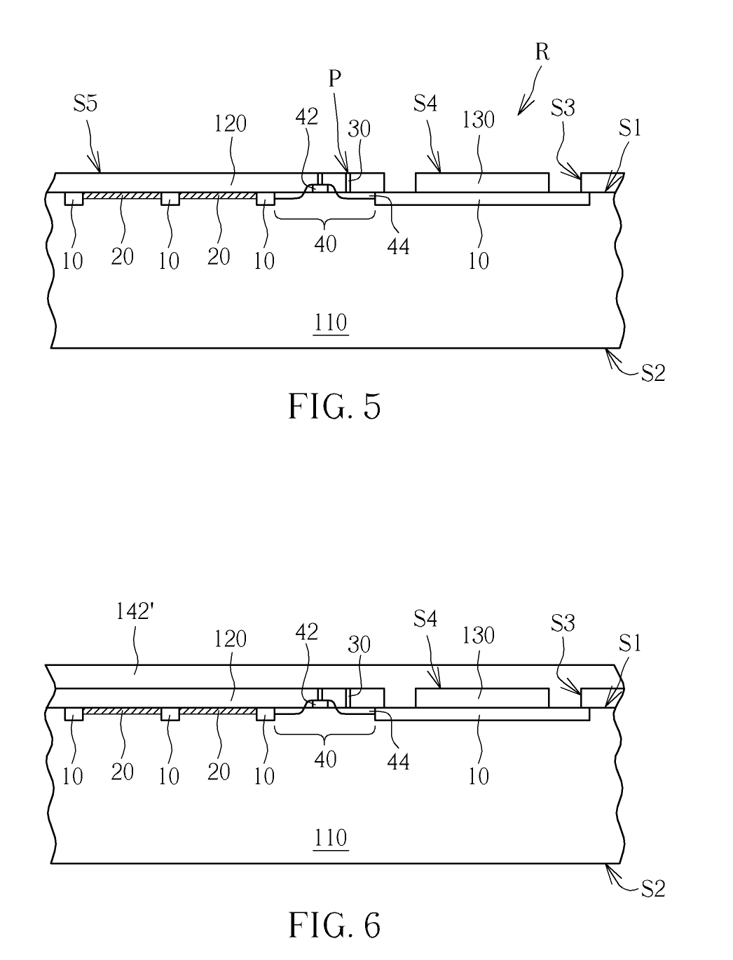

As shown in FIGS. 3-5, a bond pad 130 is formed on the substrate 110 and in the dielectric layer 120. In details, as shown in FIG. 3, the dielectric layer 120 is patterned to form a recess R and expose apart of the isolation structure 10 by performing a photolithography process. As shown in FIG. 4, a bond pad material 130′ entirely covers the exposing part of the isolation structure 10 and the dielectric layer 120. As shown in FIG. 5, a part of the bond pad material 130′ is removed and only the bond pad material 130′ in the recess R remains to form a bond pad 130. The bond pad 130 may include low resistance materials such as aluminum or aluminum copper alloys, but it is not limited thereto. Specifically, the bond pad 130 is mainly composed of aluminum, and it may be doped with little quantities of silicon, copper, manganese or etc for improving the capabilities of resistivity and electromigration resistance.

It is worth noting that, due to the bond pad 130 being mainly composed of aluminum or aluminum copper alloys etc, and metal structures such as the contact plugs 30 or other interconnect structures being mainly composed of materials such as copper or tungsten, the bond pad 130 and the metal structures are therefore substantially composed of different materials. Moreover, as shown in FIG. 5, the top surface S4 of the bond pad 130 is leveled with the top surface S5 of the dielectric layer 120(, depending upon the thickness of the bond pad 130), the bond pad 130 and the contact plugs 30 are substantially at the same level or in the same dielectric layer 120(, depending upon the thickness of the bond pad 130), and the top surface S4 of the bond pad 130 is leveled with a top surface P of the contact plugs 30(, depending upon the thickness of the bond pad 130). In another embodiment, the top surface S4 of the bond pad 130 may be higher than the top surface S5 of the dielectric layer 120. In other words, in order to form a bond pad (not shown) with a deeper thickness than this embodiment, other interdielectric layers (not shown) or inter metal dielectric (IMD) layers (not shown) are formed on the dielectric layer 120 and then the interdielectric layer, the inter metal dielectric (IMD) layer and the dielectric layer 120 are patterned to form an opening with a deeper depth than in this embodiment, so that a bond pad (not shown) can be formed in the opening (not shown), wherein the space for forming interconnect structures may be formed while the interdielectric layer, the inter metal dielectric (IMD) and the dielectric layer 120 are patterned. Furthermore, in a preferred embodiment, an opening for containing a bond pad may be formed in upper inter metal dielectric (IMD) layers, and interconnect structures may be formed under the opening early, wherein the interconnect structures are preferred to be form at the edge for preventing from affecting bonding. So, flatness problems occur later caused by the over-depth of the opening can be avoided.

In this embodiment, the recess R is formed right above the isolation structure 10, and the layout size of the recess R is smaller than the layout size of the isolation structure 10, so that the bond pad formed in the recess R can electrically isolate the substrate 110. In another embodiment, the recess R may be directly formed on the substrate 110. In one case, as a part of the bond pad material 130′ is removed to form the bond pad 130 in the recess R, spacers (not shown) may be formed on sidewalls S3 of the recess R, but it is not limited thereto.

As shown in FIG. 6, a first dielectric layer (not shown) is formed to entirely cover the bond pad 130 and the dielectric layer 120, and the first dielectric layer (not shown) is planarized to form a first dielectric layer 142′. In this embodiment, the first dielectric layer 142′ is an inter metal dielectric (IMD) layer, which is an oxide layer, but it is not limited thereto. In another embodiment, the first dielectric layer 142′ may be an interdielectric layer but not limited thereto.

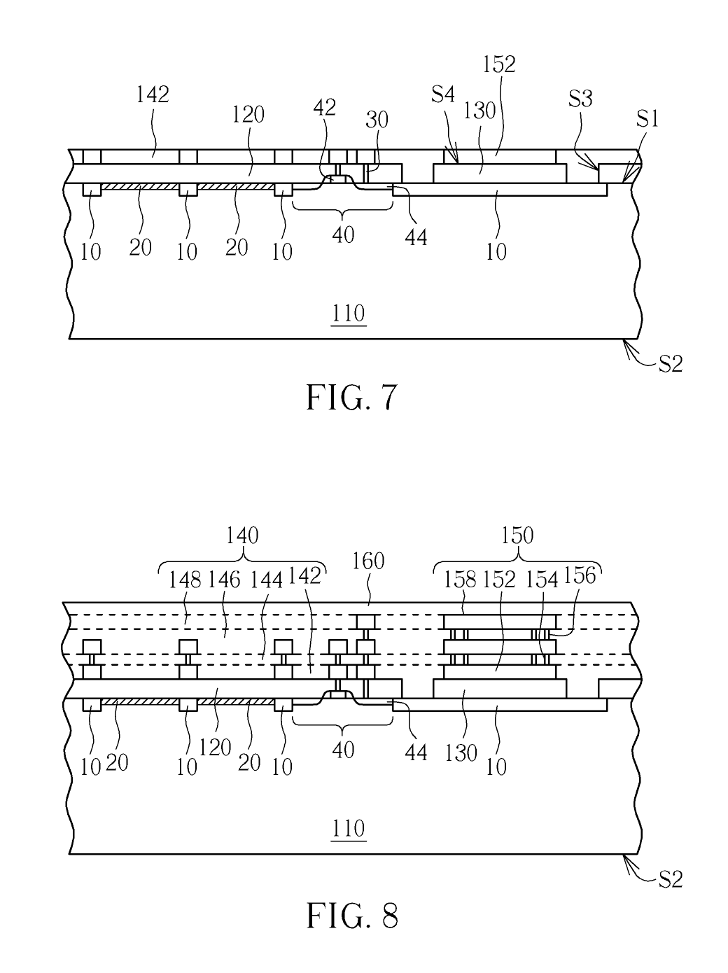

As shown in FIG. 7, an interconnect structure 152 is formed in a patterned first dielectric layer 142. In details, the first dielectric layer 142′ is patterned to form the patterned first dielectric layer 142. Metals are filled into the patterned first dielectric layer 142 to form an interconnect structure 152. The metals may include low resistance materials such as copper or tungsten etc.

As shown in FIG. 8, the steps of forming the patterned first dielectric layer 142 and forming the interconnect structure 152 shown in FIGS. 6-7 can be performed repeatedly, to form a multilayer first dielectric layer 140 and a multilayer interconnect structure 150. For instance, the patterned first dielectric layers 144, 146,148 are formed respectively and metals are filled into the patterned first dielectric layers 144, 146, 148, so that the multilayer interconnect structure 150 including four layers of the interconnect structures 152, 154, 156-158 and the multilayer first dielectric layer 140 including the layers of patterned first dielectric layers 144, 146, 148 are formed. As shown in FIG. 8, a damascene processes are performed in this embodiment to form four layers of the patterned first dielectric layers 144, 146, 148 respectively, and the four layers will merge into the multilayer first dielectric layer 140. In another embodiment, the multilayer first dielectric layer 140 may be formed by other processes, and the number of layers of the interconnect structures are not limited. Then, an isolating layer 160 is formed to entirely cover the multilayer interconnect structure 150 and the multilayer first dielectric layer 140. The isolating layer 160 may be an oxide layer, but it is not limited thereto.

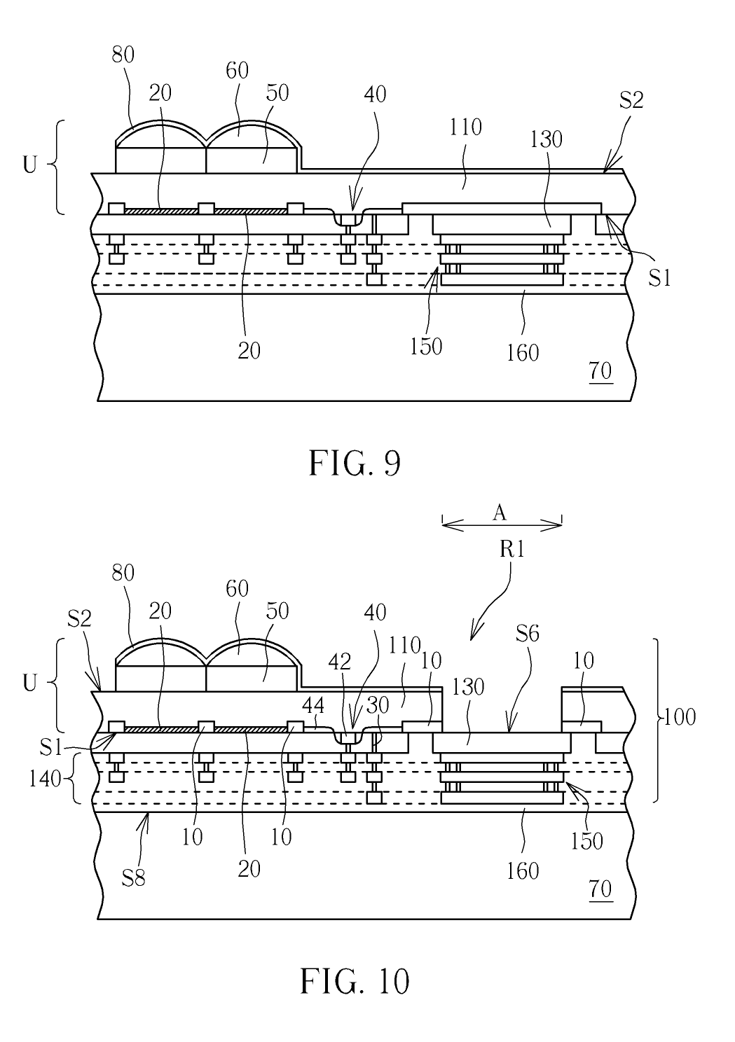

As shown in FIG. 9, the structure of FIG. 8 is inverted, and the isolating layer 160 is formed on a carrier wafer 70, the substrate 110 is thinned down from the back side S2, and a color filter unit 50, a microlens array 60 and a passivation layer 80 are sequentially formed, wherein the color filter unit 50 and the microlens array 60 align to the photodiode array 20, enabling incident beams to be received and focused by the photodiode array 20. This way, the photodiode array 20 can sense the incident beams, and then transform the incident beams into electrical current flowing to MOS transistors to transfer digital signals. An image sensor unit U is now formed, which includes the photodiode array 20, the MOS transistor 40, the color filter unit 50 and the microlens array 60 etc. Furthermore, as shown in the figure, the image sensor unit U and the multilayer interconnect structure 150 are respectively located on both sides of the bond pad 130. In this embodiment, the bond pad 130 is just located in the dielectric layer 120. In another embodiment, the bond pad 130 may be just located on at least one of the patterned first dielectric layer 144, 146, 148 of the multilayer first dielectric layer 140, or the bond pad 130 may be located in the dielectric layer 120 and extend to the multilayer first dielectric layer 140.

As shown in FIG. 10, parts of the substrate 110 and the isolation structure 10 formed therein are removed through etching to form the recess R1 and expose at least a part of the bond pad 130. Thus, a bonding ball of a solder bump (not shown) or a bonding ball of a wire bond (not shown) can be formed on a front side S6 of the bond pad 130, and the bonding ball (not shown) and the multilayer interconnect structure 150 are therefore respectively located on both sides of the bond pad 130 due to the multilayer interconnect structure 150 being located on a back side S7 of the bond pad 130. At this time, the back side illumination (BSI) image sensor 100 of this embodiment is formed.

According to the above, the problems of previous embodiment can be solved in this embodiment. In details, only parts of the substrate 110 and the isolation structure 10 therein need to be etched to expose the bond pad 130, so that the difficulty of etching can be overcome. (2) Due to the multilayer interconnect structure 150 being located on the back side S7 of the bond pad 130 and overlapping the bond pad 130, the size of the bond pad 130 needs to be as large as the size of the multilayer interconnect structure 150, without further forming an area (as the area A described in before embodiment) for electrical connection, so that the volume of the image sensor 100 can be reduced. In addition, although the size of the bond pad 130 just as large as the size of the multilayer interconnect structure 150 needs to be formed to achieve the capability of electrical connection, the size of the bond pad 130 is not restricted to it, and depends upon the requirements. Thus, the disposed volume and shape of the bond pad 130 of this embodiment can be more flexible. (3) In processes, the bond pad 130 of this embodiment is directly formed on the isolation structure 10 or the substrate 10, so that the formation of the divot D of the previous embodiment will not occur. The isolating layer 160 is located on the multilayer interconnect structure 150 and the multilayer first dielectric layer 140, and the multilayer interconnect structure 150 is obtained by filling metals into the multilayer first dielectric layer 140, that will not generate the divot D, therefore the surface S8 of the isolating layer 160 located on the multilayer interconnect structure 150 and the multilayer first dielectric layer 140 is flat, and the isolating layer 160 can contact the carrier wafer 70 statically and closely. (4) The bond pad 130 is directly formed on the isolation structure 10 or the substrate 110 in this embodiment, and then the multilayer interconnect structure 150 is formed, and the multilayer interconnect structure 150 is obtained by patterning the multilayer first dielectric layer 140 and filling metals into it, so that antenna effect will not occur, previously caused by the etching of the stacked inter metal dielectric (IMD) layer 230, or the likes, with a deep depth.

To summarize, the present invention provides an integrated circuit structure, a back side illumination (BSI) image sensor and an integrated circuit process, which directly forms a bond pad on a substrate, forms an interconnect structure on the back side of the bond pad, and then etches the substrate to expose the front side of the bond pad, enabling the bond pad to electrically connect outer circuits. Therefore, the integrated circuit structure, the back side illumination (BSI) image sensor and the integrated circuit process have the following advantages: it overcomes the difficulties of exposing the bond pad through etching; the volume of the bond pad shrinks, so that the volume of the integrated circuit structure or the back side illumination (BSI) image sensor shrinks too; a surface of an isolating layer used for connecting a carrier wafer can be flatter; no antenna effect caused by etching a stacked inter metal dielectric (IMD) layer for filling the bond pad material will occur.

Those skilled in the art will readily observe that numerous modifications and alterations of the device and method may be made while retaining the teachings of the invention. Accordingly, the above disclosure should be construed as limited only by the metes and bounds of the appended claims.

1. An integrated circuit structure, comprising:
a bond pad and a metal structure located in a dielectric layer, wherein the bond pad and the metal structure are substantially composed of different materials.

2. The integrated circuit structure according to claim 1, wherein the metal structure comprises a contact plug.

3. The integrated circuit structure according to claim 2, wherein a top surface of the bond pad is leveled with a top surface of the contact plug.

4. The integrated circuit structure according to claim 1, wherein the bond pad is composed of aluminum or aluminum copper alloys.

5. The integrated circuit structure according to claim 1, wherein the metal structure comprises an interconnect structure.

6. The integrated circuit structure according to claim 1, wherein the metal structure is composed of copper or tungsten.

7. The integrated circuit structure according to claim 1, wherein the dielectric layer comprises an interdielectric layer or an inter metal dielectric (IMD) layer.

8. The integrated circuit structure according to claim 1, wherein a top surface of the bond pad is leveled with a top surface of the dielectric layer.

9. The integrated circuit structure according to claim 1, wherein the bond pad comprises a front side and a back side, and the integrated circuit structure further comprises an interconnect structure directly contacting the back side.

10. The integrated circuit structure according to claim 9, further comprising:
a bonding ball located on the bond pad, and the bonding ball and the interconnect structure respectively located on either side of the bond pad.

11. The integrated circuit structure according to claim 1, wherein the integrated circuit structure further comprises a back side illumination (BSI) image sensor.

12. A back side illumination (BSI) image sensor, comprising:
an image sensor unit and an interconnect structure respectively located on both sides of a bond pad, and the image sensor unit comprising a photodiode array located in a substrate.

13. The back side illumination (BSI) image sensor according to claim 12, further comprising:
a contact plug and the bond pad located in the same dielectric layer.

14. The back side illumination (BSI) image sensor according to claim 13, wherein a top surface of the bond pad is leveled with a top surface of the contact plug.

15. The back side illumination (BSI) image sensor according to claim 13, wherein the dielectric layer comprises an interdielectric layer or an inter metal dielectric (IMD) layer.

16. The back side illumination (BSI) image sensor according to claim 12, wherein the bond pad is composed of aluminum or aluminum copper alloys.

17. The back side illumination (BSI) image sensor according to claim 12, wherein the interconnect structure is composed of copper.

18. The back side illumination (BSI) image sensor according to claim 12, further comprising:
a bonding ball located on the bond pad, and the bonding ball and the interconnect structure respectively located on both sides of the bond pad.

19. An integrated circuit process, comprising:
forming a dielectric layer on a front side of a substrate;
forming a bond pad on the substrate and in the dielectric layer;
forming a first dielectric layer on the bond pad and the dielectric layer;
forming an interconnect structure in the first dielectric layer; and
forming a recess in a back side of the substrate to expose the bond pad.

20. The integrated circuit process according to claim 19, further comprising:
forming a MOS transistor on the substrate before the dielectric layer is formed.

21. The integrated circuit process according to claim 19, wherein the dielectric layer comprises an interdielectric layer.

22. The integrated circuit process according to claim 19, wherein the substrate comprises a shallow trench isolation structure, and the bond pad is formed right above the shallow trench isolation structure.

23. The integrated circuit process according to claim 19, wherein the method of forming the bond pad comprises:
patterning the dielectric layer to form an opening and expose part of the substrate;
entirely covering a bond pad material on the part of the substrate and the dielectric layer; and
removing a part of the bond pad material to form the bond pad in the opening.

24. The integrated circuit process according to claim 19, wherein the first dielectric layer comprises an interdielectric layer or an inter metal dielectric (IMD) layer.

25. The integrated circuit process according to claim 19, wherein the method of forming the interconnect structure comprises:
patterning the first dielectric layer; and
filling metals in the patterned first dielectric layer to form the interconnect structure.

26. The integrated circuit process according to claim 19, wherein the steps of forming the first dielectric layer and the interconnect structure are performed repeatedly to form multilayers of the first dielectric layer and the interconnect structure.

27. The integrated circuit process according to claim 19, further comprising:
forming an isolating layer on the first dielectric layer and the interconnect structure.

28. The integrated circuit process according to claim 19, further comprising:
forming a color filter unit on the back side of the substrate after the interconnect structure is formed.
